(19) United States
(12) Patent Application Publication
(10) Pub. No.: US 2017/0033236 A1
(43) Pub. Date: Feb. 2, 2017

(54) THIN-FILM TRANSISTOR STRUCTURE

(71) Applicant: GIANTPLUS TECHNOLOGY CO., LTD., MIAO-LI COUNTY 351 (TW)

(72) Inventors: KAI-JU CHOU, MIAO-LI COUNTY 351 (TW); CHE-YAO WU, MIAO-LI COUNTY 351 (TW); KU-HUANG LAI, MIAO-LI COUNTY 351 (TW); I-TA JIANG, MIAO-LI COUNTY 351 (TW)

(21) Appl. No.: 14/932,215

(22) Filed: Nov. 4, 2015

(30) Foreign Application Priority Data
Jul. 31, 2015 (TW) 104124874

(51) Int. Cl. H01L 29/786

(52) U.S. Cl. CPC H01L 29/78648; H01L 29/78663; H01L 29/78672; H01L 29/78696

(57) ABSTRACT

The present invention provides a thin-film transistor structure, which comprises a substrate, a first metal layer, a first buffer layer, a semiconductor layer, a second metal layer, a second buffer layer, and a third metal layer. The second metal layer includes a gap region; the semiconductor layer includes a channel region. The present invention uses the first and third metal layers to form double gates. By controlling the channel region using the double-gate structure, the turn-on current of the thin-film transistor can be enhanced and thus achieving the efficacy of improving the driving efficiency of the device.

### FIELD OF THE INVENTION

The present invention relates generally to a thin-film transistor structure, and particularly to a thin-film transistor structure having double gates.

### BACKGROUND OF THE INVENTION

In the industry of flat-panel display, thin-film transistor liquid crystal displays (TFT-LCD) are popular products presently. Owing to massive adoption of thin-film transistors, the quality of thin-film transistors, such as the turn-on current, has decisive influence on the overall quality of liquid crystal displays.

When a thin-film transistor is turned on, electrons will be conducted from the source to the drain. Among thin-film transistors, according to the material of the semiconductor layer, they can be further classified into polysilicon thin-film transistors and amorphous-silicon thin-film transistors. Polysilicon thin-film transistors have the advantage of higher carrier mobility. Unfortunately, they also have the disadvantage of larger leakage current. On the contrary, compared with polysilicon thin-film transistors, amorphous-silicon thin-film transistors have lower carrier mobility. This factor leads to higher resistivity in amorphous-silicon thin-film transistors and thereby limiting the conductivity of the devices. Consequently, the turn-on current of amorphous thin-film transistors indirectly lead to inferior driving efficiency.

Accordingly, the present invention provides a novel thin-film transistor with high driving efficiency for improving the drawbacks as described above.

### SUMMARY

An objective of the present invention is to provide a thin-film transistor structure, which includes a third metal layer for improving the driving characteristics of thin-film transistors.

Another objective of the present invention is to provide a thin-film transistor structure, which includes a third metal layer for optimizing the circuit layout.

In order to achieve the objectives and efficacies as described above, the present invention provides a thin-film transistor structure, which comprises a substrate, a first metal layer, a first buffer layer, a semiconductor layer, a second metal layer, a second buffer layer, and a third metal layer. The first metal layer is disposed on the substrate. The first buffer layer covers the substrate and the first metal layer. The semiconductor layer is disposed on the first buffer layer. The second metal layer is disposed on the semiconductor layer and includes a gap region. The second buffer layer covers the second metal layer and the semiconductor layer. The third metal layer is disposed on the buffer layer. The present invention uses the first and third metal layers located above and under the semiconductor layer to form double gates. Thereby, the turn-on current of the thin-film transistor can be enhanced and thus improving the driving efficiency as well as optimizing the circuit layout.

### BRIEF DESCRIPTION OF THE DRAWINGS

FIG. 1B shows a structural schematic diagram according to the first embodiment of the present invention;

FIG. 1B shows a top view according to the first embodiment of the present invention;

FIGS. 2A to 2F show process flowcharts according to the first embodiment of the present invention;

FIG. 3A shows a structural schematic diagram according to the second embodiment of the present invention;

FIG. 3B shows a top view according to the second embodiment of the present invention;

FIG. 4A shows a structural schematic diagram according to the third embodiment of the present invention; and

FIG. 4B shows a top view according to the third embodiment of the present invention.

### DETAILED DESCRIPTION

In order to make the structure and characteristics as well as the effectiveness of the present invention to be further understood, the detailed description of the present invention is provided as follows along with embodiments and accompanying figures.

Considering the demands for the driving efficiency of thin-film transistors and the miniaturization of circuit layout, the present invention provides a thin-film transistor structure for increasing the turn-on current and thereby achieving improving the driving efficiency as well as optimizing the circuit layout.

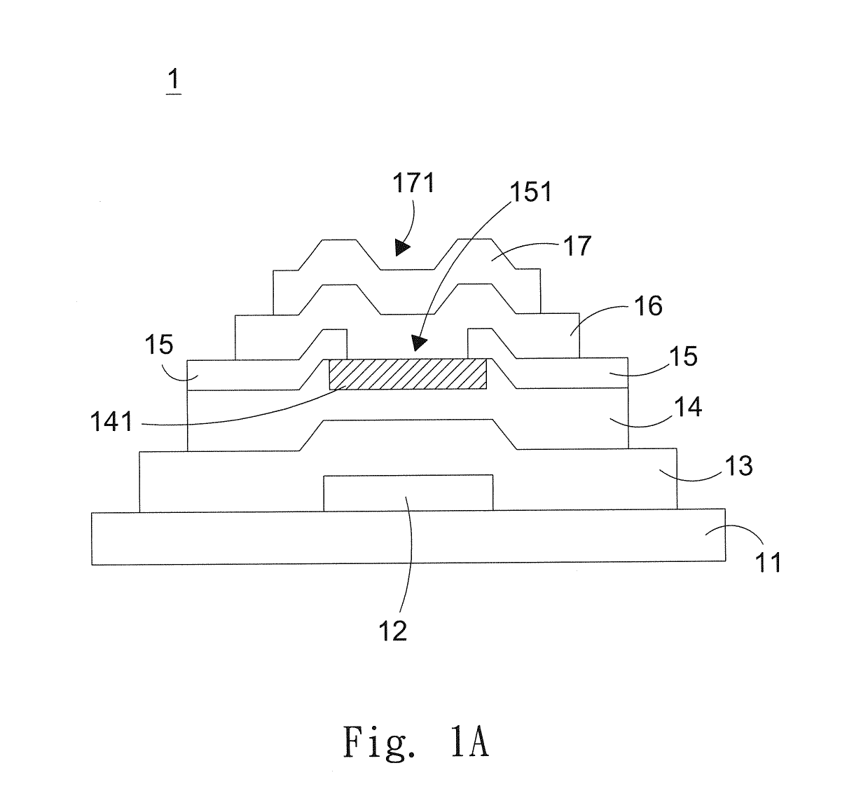

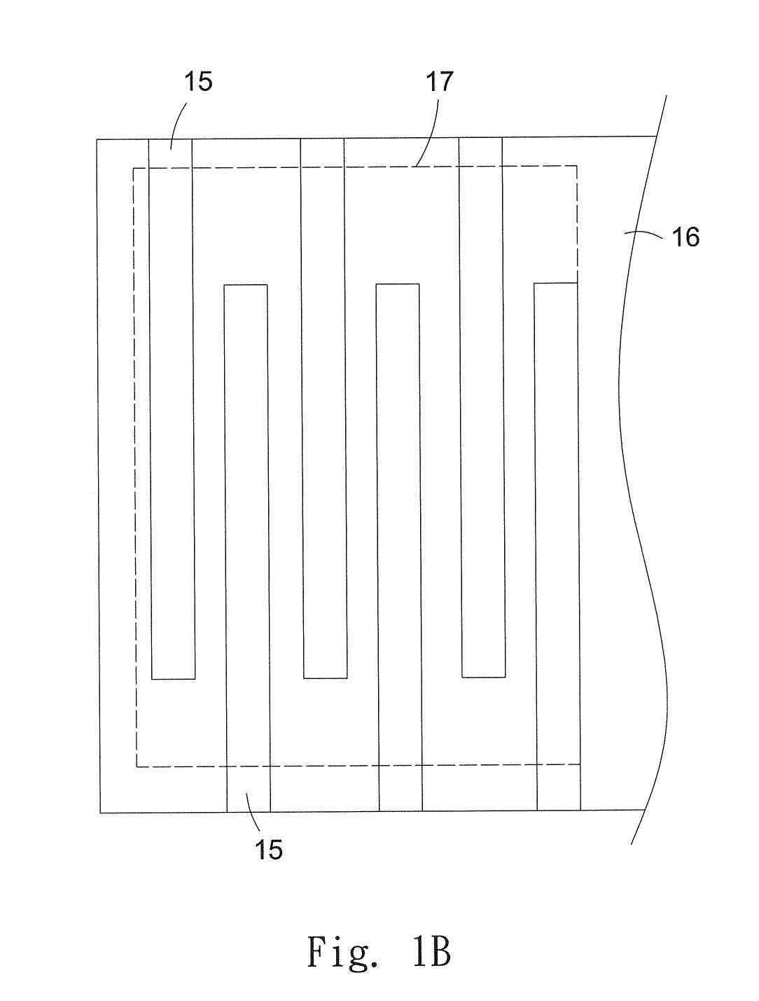

First, please refer to FIG. 1A, which shows a structural schematic diagram according to the first embodiment of the present invention. As shown in the figure, the components and their connection according to the present embodiment are illustrated. The present embodiment provides a thin-film transistor structure 1, which comprises a substrate 11, a first metal layer 12, a first buffer layer 13, a semiconductor layer 14, a second metal layer 15, a second buffer layer 16, and a third metal layer 17. In addition, the semiconductor layer 14 according to the present embodiment includes a channel region 141. The second metal layer 15 includes a gap region 151. The second buffer layer 16 includes at least a recess 171 there above.

Please refer to FIG. 1B, which shows a top view according to the first embodiment of the present invention. The figure illustrates the relationship between the second and third metal layers 15, 17. According to the top view, the second metal layer 15 includes a plurality of parts acting as the source and drain of the thin-film transistor. The region enclosed by the dotted line is the location of the third metal layer 17 corresponding to the gap region 151 of the second metal layer 15. As shown in the figure, the third metal layer 17 according to the present embodiment covers the gap region 151 completely.

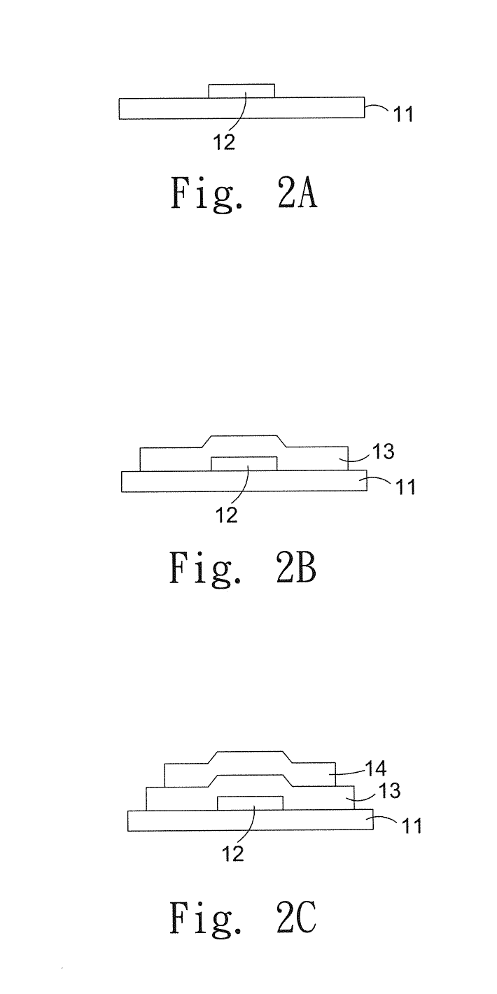

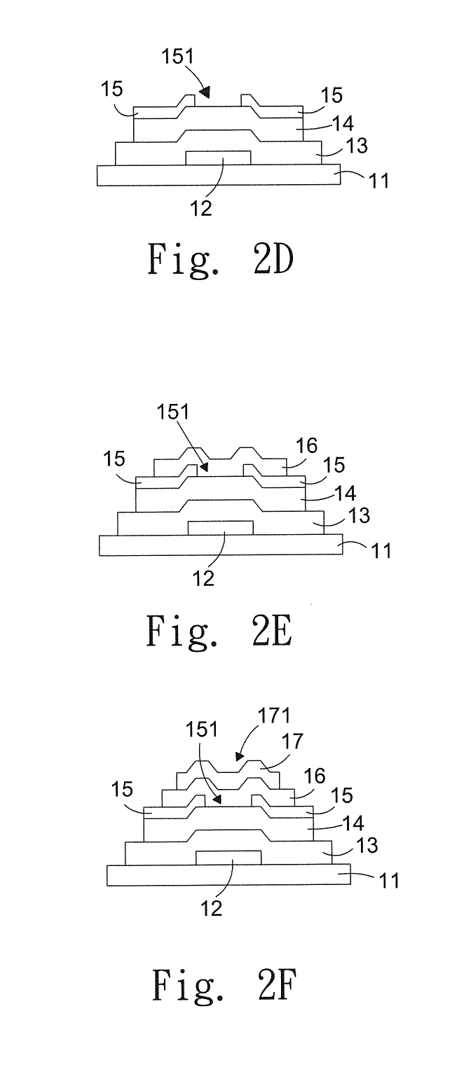

Please refer to FIGS. 2A to 2F, which show process flowcharts according to the first embodiment of the present invention. As shown in the figures, the connection among the components according to the present embodiment is illustrated. As shown in FIG. 2A, the first metal layer 12 is disposed on the substrate 11 and used as a gate of the thin-film transistor. As shown in FIG. 2B, the first buffer layer 13 covers the substrate 11 and the first metal layer 12. As shown in FIG. 2C, the semiconductor layer 14 is disposed on the first buffer layer 13. The material of the semiconductor layer 14 can be, but not limited to, amorphous silicon. For example, it also can be polysilicon. As shown in FIG. 2D, the second metal layer 15 which include a gap region 151 is disposed on the semiconductor layer 14. The gap region 151 divides the second metal layer 15 into two parts used as the source and the drain of the thin-film transistor, respectively. When an appropriate voltage is applied to the thin-film transistor, electrons will be conducted in the semiconductor layer 14 and thus connecting electrically both parts of the second metal layer 15 separated at the gap region 151. As shown in FIG. 2E, the second buffer layer 16 covers the second metal layer 15 and the semiconductor layer 14. Moreover, as shown in FIG. 2F, the third metal layer 17 is disposed on the second buffer layer 16. The width of the third metal layer 17 is greater than the width of the gap region 151. The material of the third metal layer 17 can be metal elements, metal compounds, or metal oxides. The third metal layer 17 can act as another gate of the thin-film transistor.

Besides, the width of the first metal layer 12 according to the present embodiment is close to the width of the gap region 151. In other words, the width of the first metal layer 12 can be greater than, equal to, and less than the width of the gap region 151. According to a preferred embodiment, the width of the first metal layer 12 is greater than the width of the gap region 151. In addition, as shown in FIG. 2F, the width of the channel region 141 according to the present embodiment can be greater than, equal to, or less than the width of the third metal layer 17 according to the design requirements for adjusting the characteristics of the thin-film transistor structure.

The thin-film transistor structure 1 according to the present embodiment uses the third metal layer 17 to be another gate different from the one using the first metal layer 12. The semiconductor layer 15 is controlled by the gates located above and under using the first and third metal layers 12, 17, respectively, and thus forming a double-gate structure. By using the double-gate structure, the channel region 141 is controlled by the double gates and hence enhancing the switching speed and turn-on current of the device. Consequently, the turn-on current and the discharge rate of the overall thin-film transistor structure 1 are improved, leading to enhancement in the driving performance.

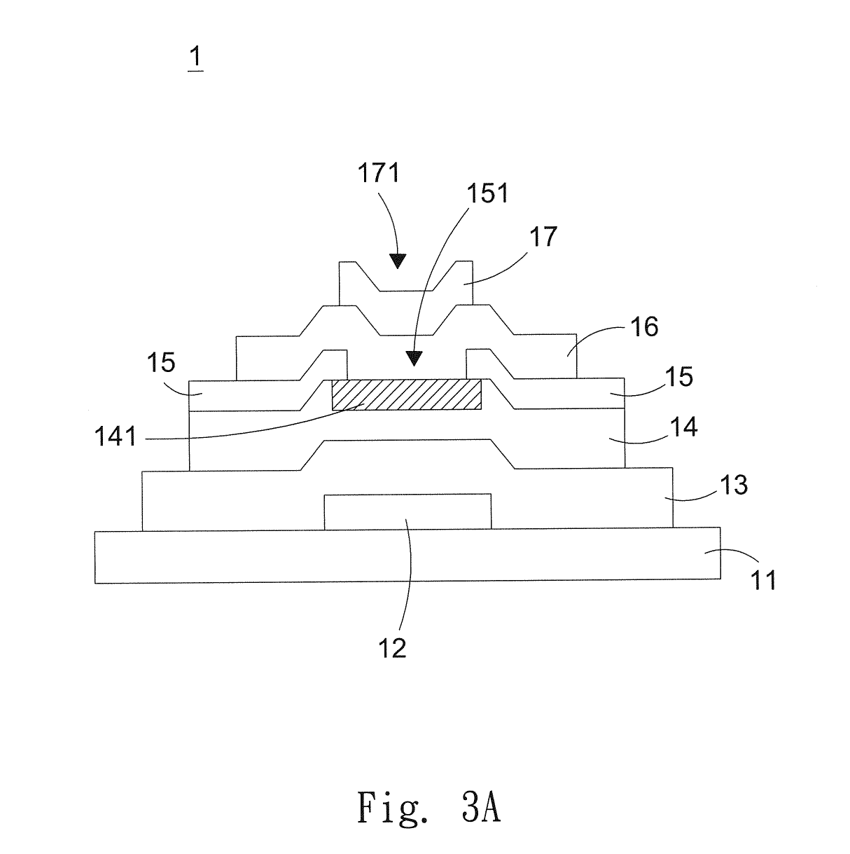

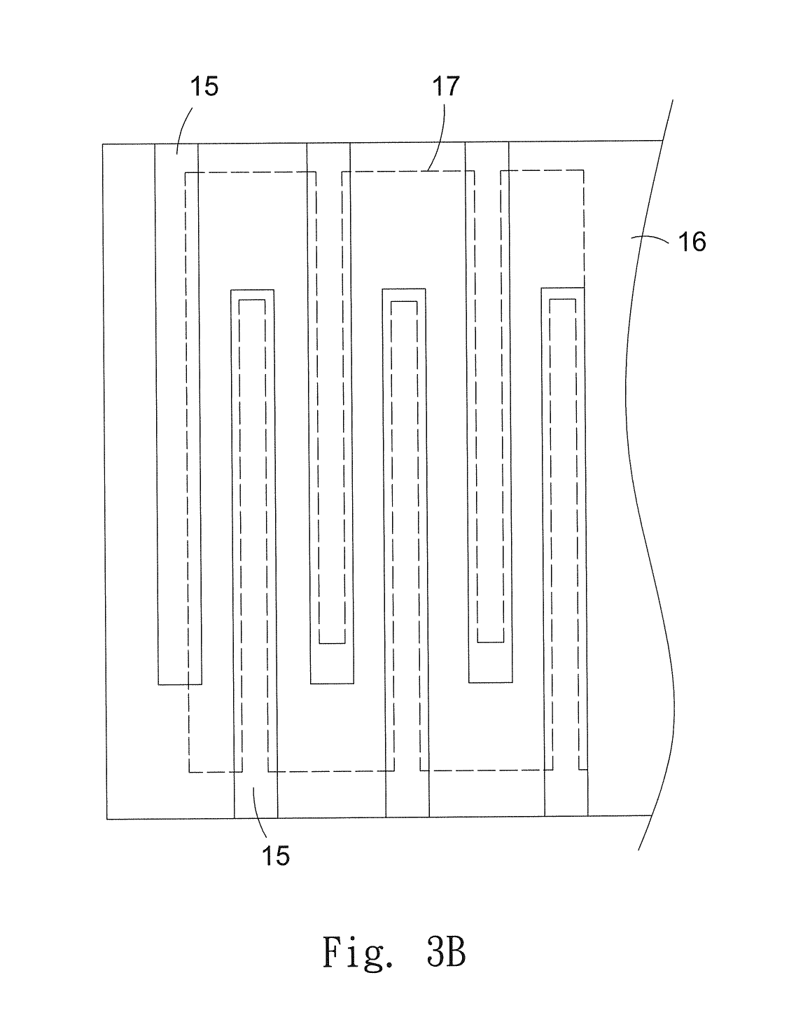

Please refer to FIG. 3A, which shows a structural schematic diagram according to the second embodiment of the present invention. As shown in the figure, the components and their connection according to the present embodiment are illustrated. The difference between the present embodiment and the previous one is that, according to the present embodiment, the width of the third metal layer 17 is equal to that of the gap region 151. The detailed components and their connection are identical to those in the previous embodiment. Hence, the details will not be described again.

Please refer to FIG. 3B, which shows a top view according to the second embodiment of the present invention. The figure illustrates the relationship between the second and third metal layers 15, 17. According to the top view, the second metal layer 15 includes a plurality of parts acting as the source and drain of the thin-film transistor. The region enclosed by the dotted line is the location of the third metal layer 17 corresponding to the gap region 151 of the second metal layer 15. As shown in the figure, the width of the third metal layer 17 according to the present embodiment is greater than the width of the gap region 151. Please refer again to FIG. 3A. The width of the channel region 141 according to the present invention further represents the distance by which the electrons travel from any terminal of the second metal layer 15 to the opposing terminal. In other words, because the channel region 141 has to be connected directly with the both terminals of the second metal layer 15, it is deduced that the width of the channel region 141 will be the width of the gap region 151 plus the widths on the both terminals of the second metal layer 15. Thereby, the width of the channel region 141 will be slightly greater than that of the gap region 151. According to the above description and FIG. 3B, the difference between the present embodiment and the previous one is that, according to the present embodiment, the third metal layer 17 corresponds to the channel region 141 and covers the second buffer layer 16.

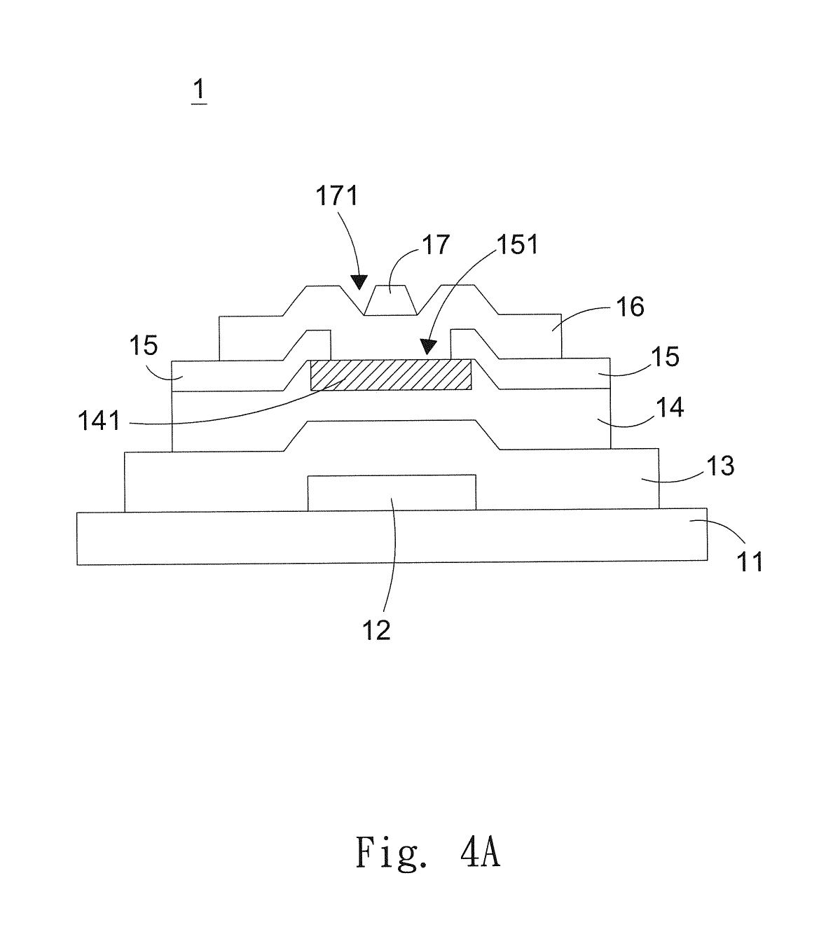

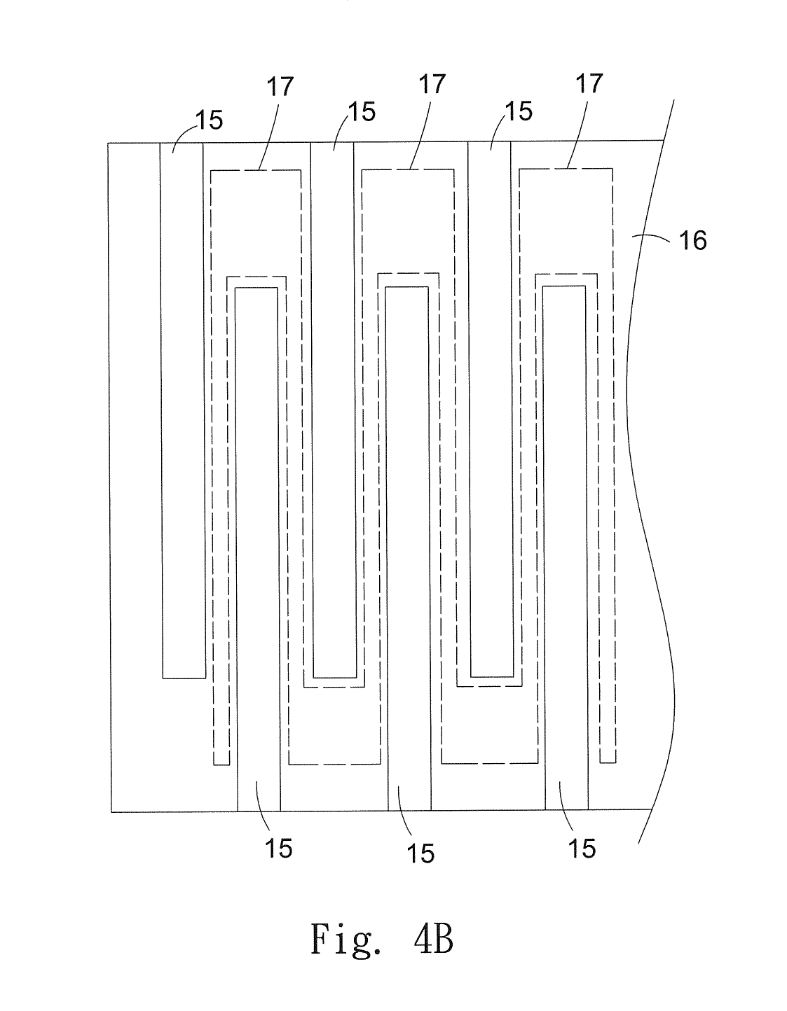

FIG. 4A shows a structural schematic diagram according to the third embodiment of the present invention. As shown in the figure, the components and their connection according to the present embodiment are illustrated. The difference between the present embodiment and the previous embodiments is that, according to the present embodiment, the width of the third metal layer 17 is less than that of the gap region 151. The detailed components and their connection are identical to those in the previous embodiment. Hence, the details will not be described again.

Please refer to FIG. 4B, which shows a top view according to the third embodiment of the present invention. The figure illustrates the relationship between the second and third metal layers 15, 17. According to the top view, the second metal layer 15 includes a plurality of parts acting as the source and drain of the thin-film transistor. The region enclosed by the dotted line is the location of the third metal layer 17 corresponding to the gap region 151 of the second metal layer 15. As shown in the figure, the difference between the present embodiment and the previous embodiments is that, according to the present embodiment, the third metal layer 17 is disposed within the range covered by the width of the channel region 141 or the gap region 151.

To sum up, the present invention provides a thin-film transistor structure, which comprises a substrate, a first metal layer, a first buffer layer, a semiconductor layer, a second metal layer, a second buffer layer, and a third metal layer. The first metal layer is disposed on the substrate. The first buffer layer covers the substrate and the first metal layer. The semiconductor layer is disposed on the first buffer layer. The second metal layer is disposed on the semiconductor layer and includes a gap region. The second buffer layer covers the second metal layer and the semiconductor layer. The third metal layer is disposed on the buffer layer. The present invention uses the first and third metal layers located above and under the semiconductor layer to form double gates for improving the driving efficiency of the thin-film transistor as well as optimizing the circuit layout.

Accordingly, the present invention conforms to the legal requirements owing to its novelty, non-obviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A thin-film transistor structure, comprising:
a substrate;
a first metal layer, disposed on said substrate;
a first buffer layer, covering said substrate and said first metal layer;
a semiconductor layer, disposed on said first buffer layer;
a second metal layer, disposed on said semiconductor layer, and including a gap region;
a second buffer layer, covering said second metal layer; and
a third metal layer, disposed on said second buffer layer.

2. The thin-film transistor structure of claim 1, wherein the width of said first metal layer is greater than the width of said gap region.

3. The thin-film transistor structure of claim 1, wherein said second buffer layer includes at least a recess there above, and said third metal layer is disposed in said recess.

4. The thin-film transistor structure of claim 1, wherein the width of said third metal layer is greater than the width of said gap region.

5. The thin-film transistor structure of claim 1, wherein the width of said third metal layer is equal to the width of said gap region.

6. The thin-film transistor structure of claim 1, wherein the width of said third metal layer is less than the width of said gap region.

7. The thin-film transistor structure of claim 1, wherein said semiconductor layer includes a channel region.

8. The thin-film transistor structure of claim 1, wherein the width of said channel region is less than the width of said third metal layer.

9. The thin-film transistor structure of claim 1, wherein the width of said channel region is equal to the width of said third metal layer.

10. The thin-film transistor structure of claim 1, wherein the width of said channel region is greater than the width of said third metal layer.
